(19) United States
(12) Patent Application Publication
(10) Pub. No.: US 2015/0294932 A1
(43) Pub. Date: Oct. 15, 2015

(54) SEMICONDUCTOR PACKAGE SUBSTRATE

(71) Applicant: Samsung Electro-Mechanics Co., Ltd., Suwon-Si (KR)

(72) Inventors: Kwang Il NOH, Yeondong-myeon (KR); Dong Hoon HAN, Yeondong-myeon (KR)

(21) Appl. No.: 14/537,657

(22) Filed: Nov. 10, 2014

(30) Foreign Application Priority Data
Apr. 10, 2014 (KR) 10-2014-0042929

(51) Int. Cl. H01L 23/498; H05K 1/09

(52) U.S. Cl. CPC H01L 23/49838; H01L 23/49866; H05K 1/092

(57) ABSTRACT

The present invention relates to a semiconductor package substrate, and more particularly, to a semiconductor package substrate that can prevent warpage by minimizing the difference in the residual ratio of copper between a substrate region and a dummy region or between upper and lower surfaces of the dummy region and prevent a molding material applied to the substrate region from being introduced into the dummy region by patterns formed in the dummy region.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2014-0042929, entitled filed Apr. 10, 2014, which is hereby incorporated by reference in its entirety into this application.

### BACKGROUND OF THE INVENTION

1. Field of the Invention

The present invention relates to a semiconductor package substrate, and more particularly, to a semiconductor package substrate that can control warpage easily.

2. Description of the Related Art

In recent times, according to the miniaturization, densification, and integration of semiconductor package substrates, package substrate assembly and manufacturing companies have much interest in precision mounting technology. In particular, as the package substrate becomes thinner, the importance of improvement in warpage of the substrate is being increased in a manufacturing process of the semiconductor package substrate and a soldering process of electrically bonding the package substrate on a main board.

The semiconductor package substrate consists of a substrate region in which unit substrates for individually mounting semiconductor chips thereon are divided in the form of units and a dummy region formed around the substrate region. At this time, the warpage of the semiconductor package substrate is affected by the dummy region, and it is efficient to control the warpage of the entire substrate by minimizing the warpage of the dummy region of an edge portion.

For example, if patterns are formed densely in the substrate region of the semiconductor package substrate and not formed in the dummy region, the excessive warpage may occur in the entire substrate when there is a significant difference in the density of the patterns between the dummy region and the substrate region.

Typically, since the coefficient of thermal expansion of copper used as a material of the patterns of the substrate region and the dummy region is about 10 to 20 ppm/° C. and the coefficient of thermal expansion of a resin material on which the patterns are formed is about 70 to 100 ppm/° C., it is difficult to control the warpage of the package substrate due to the difference in the coefficient of thermal expansion between the both members and the difference in the density of the patterns on the resin material.

### SUMMARY OF THE INVENTION

The present invention has been invented in order to overcome the above-described problems raised in the conventional semiconductor package substrate and it is, therefore, an object of the present invention to provide a semiconductor package substrate that can prevent warpage by minimizing the difference in the residual ratio of copper between a substrate region and a dummy region of the package substrate or between upper and lower surfaces of the dummy region.

Further, it is another object of the present invention to provide a semiconductor package substrate that can prevent a molding material applied to a substrate region from being introduced into a dummy region by patterns formed in the dummy region.

In accordance with one aspect of the present invention to achieve the object, there is provided a semiconductor package substrate including: a substrate region in which unit substrates are arranged in a lattice structure; and a dummy region formed in an outer portion of the substrate region, wherein a plurality of patterns having openings may be formed in the dummy region, and the openings of the patterns may be arranged in a staggered form to correspond to each other while being arranged to correspond to each other.

At this time, the pattern may consist of a horizontal portion and a pair of vertical portions bent from both ends of the horizontal portion so that the opening may be formed in the position opposite to the horizontal portion.

The horizontal portions of the patterns may be positioned in an edge portion of the substrate region in a row.

The plurality of patterns may be arranged in the dummy region in a plurality of rows, an end of the vertical portion may be positioned in the opening of the pattern, and a residual ratio of copper of the dummy region may be adjusted by the adjustment of the thickness and interval of the patterns.

Further, the patterns may be arranged on upper and lower surfaces of the dummy region, respectively, and the openings of the patterns may be arranged in directions crossing each other in the same position of the upper and lower surfaces of the dummy region while being arranged to be open in different directions on the upper and lower surfaces of the dummy region.

Further, an edge pattern may be selectively formed on one of the upper and lower surfaces of the dummy region.

In accordance with another aspect of the present invention to achieve the object, there is provided a semiconductor package substrate including: a substrate region in which circuit patterns are formed on unit substrates; and a dummy region formed in an outer portion of the substrate region and having a plurality of patterns with openings, wherein a residual ratio of copper of the dummy region with respect to a residual ratio of copper of the substrate region may be adjusted by arranging the openings of the patterns in the dummy region in a staggered form to correspond to each other.

At this time, the pattern may consist of a horizontal portion and a pair of vertical portions bent from both ends of the horizontal portion so that the opening may be formed in the position opposite to the horizontal portion.

The horizontal portions of the patterns may be positioned in an edge portion of the substrate region in a row.

The plurality of patterns may be arranged in the dummy region in a plurality of rows, an end of the vertical portion may be positioned in the opening of the pattern, and residual ratios of copper of upper and lower surfaces of the dummy region may be adjusted by the adjustment of the thickness and interval of the patterns formed on the upper and lower surfaces of the dummy region.

Further, the patterns may be arranged on the upper and lower surfaces of the dummy region in directions perpendicular to each other, and an edge pattern may be formed in an outer portion of the lower surface of the dummy region.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plan view of a semiconductor package substrate in accordance with the present invention;

FIG. 2 is an enlarged view of an upper surface of a dummy region of the semiconductor package substrate in accordance with the present invention;

FIG. 3 is an enlarged view of a lower surface of the dummy region of the semiconductor package substrate in accordance with the present invention;

FIG. 4 is an enlarged view of an embodiment of a pattern formed in the dummy region of the semiconductor package substrate in accordance with the present invention; and

FIG. 5 is an enlarged view showing the arrangement relationship of the patterns on the upper and lower surfaces of the dummy region of the semiconductor package substrate in accordance with the present invention.

### DETAILED DESCRIPTION OF THE PREFERABLE EMBODIMENTS

A matter regarding to an operational effect including a technical configuration for an object of the present invention will be clearly appreciated through the following detailed description with reference to the accompanying drawings showing preferable embodiments of the present invention.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

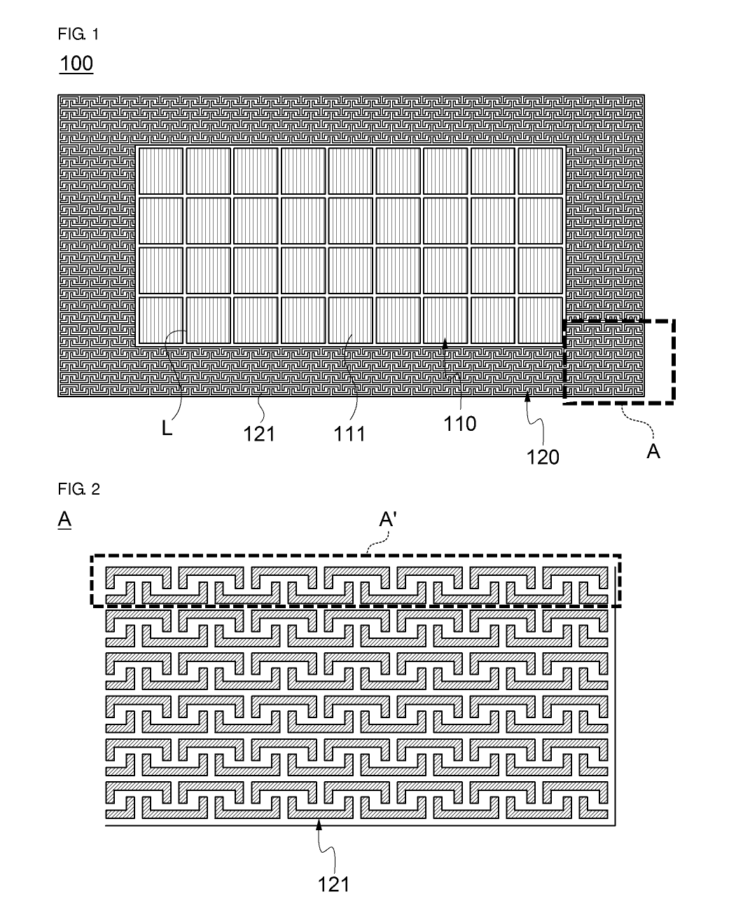

FIG. 1 is a plan view of a semiconductor package substrate in accordance with the present invention.

As shown, a semiconductor package substrate 100 of the present embodiment may consist of a substrate region 110 and a dummy region 120 which surrounds the substrate region 110.

A plurality of unit substrates 111, where semiconductor chips are individually mounted, may be arranged in the substrate region 110 in the transverse or longitudinal direction in the form of units to form a lattice structure.

Further, a molding material may be applied to an upper surface of the substrate region 110 to protect the semiconductor chip mounted on the unit substrate 111, and the substrate region 110 may be cut along a dicing line L to manufacture the unit substrate 111 after the molding material is cured.

A circuit pattern (not shown in the drawing) may be formed on the unit substrate 111 to be electrically connected to the semiconductor chip which is individually mounted on the upper surface of the unit substrate 111, and the circuit pattern may be designed in various design patterns to implement the function of the semiconductor chip.

Meanwhile, the dummy region 120 may be provided in an outer portion of the package substrate 100 as a non-functional portion in which patterns formed on upper and lower surfaces do not serve as circuits and removed when the manufacture of the semiconductor package substrate 100 is completed and thus the unit substrates 111 of the substrate region 110 are cut.

The pattern that functions as a circuit and the pattern that does not function as a circuit may be formed in the substrate region 110 and the dummy region 120, respectively, and the patterns formed in the respective regions may be made of gold (Au) or silver (Ag) but mainly made of copper (Cu).

At this time, since the pattern of the substrate region 110 may be designed by the circuit design in order for the substrate region 110 to have a predetermined residual ratio of copper, the dummy region 120 is preferred to have the same or similar residual ratio of copper to the substrate region 110.

The reason why the residual ratios of copper of the substrate region 110 and the dummy region 120 are adjusted to be the same or similar to each other to thereby minimize the difference in the residual ratio of copper is because warpage may occur during the manufacture of the package substrate due to the increase in the difference in the coefficient of thermal expansion between the respective regions by the difference in the residual ratio of copper.

Here, the residual ratio of copper means a ratio of the area occupied by a copper pattern to a unit area. The residual ratio of copper of the substrate region 110 will be defined as a ratio of the area occupied by the circuit pattern to the entire area of the substrate region 110, and the residual ratio of copper of the dummy region 120 will be defined as a ratio of the area occupied by the copper pattern to the entire area of the dummy region 120.

The semiconductor package substrate 100 of the present embodiment can minimize the warpage of the package substrate 100 by forming patterns 121 with openings in the dummy region 120 to have a predetermined regularity and minimizing the residual ratio of copper by the patterns 121 of the upper and lower surfaces of the dummy region 120 as well as minimizing the residual ratio of copper by the substrate region 110 and the patterns 121 of the dummy region 120.

In this regard, the shape of the pattern 121 formed in the dummy region 120 of the semiconductor package substrate 100 according to the present embodiment will be described in detail with reference to the following FIGS. 2 to 5.

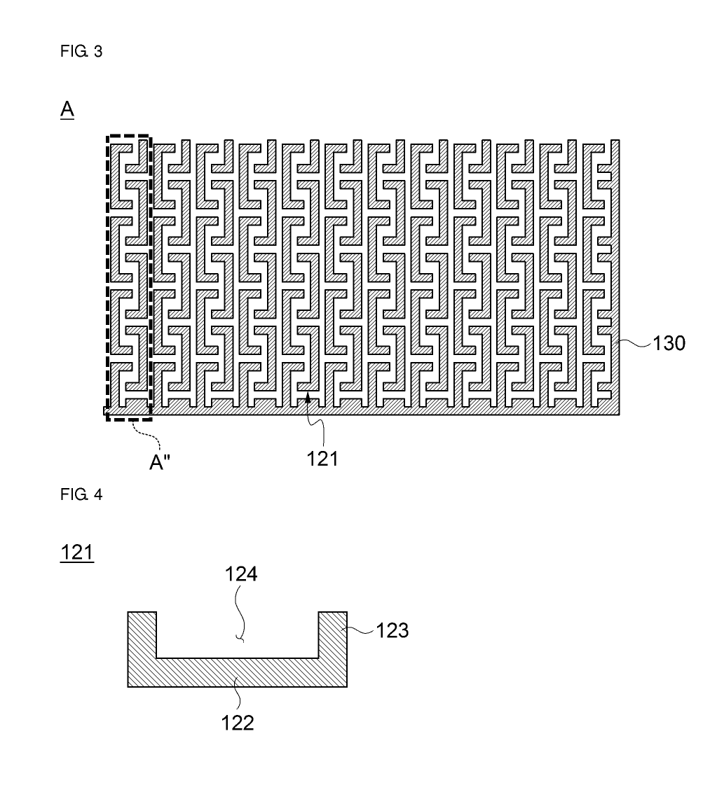

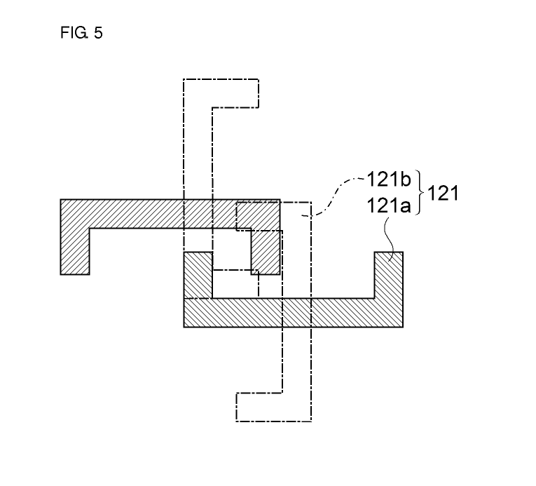

FIG. 2 is an enlarged view of the upper surface of the dummy region of the semiconductor package substrate in accordance with the present invention, FIG. 3 is an enlarged view of the lower surface of the dummy region of the semiconductor package substrate in accordance with the present invention, FIG. 4 is an enlarged view of an embodiment of the pattern formed in the dummy region of the semiconductor package substrate in accordance with the present invention, and FIG. 5 is an enlarged view showing the arrangement relationship of the patterns on the upper and lower surfaces of the dummy region of the semiconductor package substrate in accordance with the present invention.

As shown in FIGS. 2 to 5 with reference to FIG. 1, the semiconductor package substrate 100 according to the present embodiment may consist of the substrate region 110 and the dummy region 120 formed in the outer portion of the substrate region 110, and the pattern 121 with the opening 124 may be formed in the dummy region 120.

The pattern 121, as shown in FIG. 4, may consist of one horizontal portion 122 and a pair of vertical portions 123. The pair of vertical portions 123 may be respectively connected to one end and the other end of the horizontal portion 122 to face each other.

The opening 124 may be formed in the position opposite to the horizontal portion 122. Accordingly, the pattern 121 may have a rectangular shape whose one side is open.

Further, a pair of patterns 121 may be arranged in the dummy region 120 so that the respective openings 124 correspond to each other in a staggered form. That is, the patterns 121 may be arranged in the dummy region 120 like a portion A′ of FIG. 2 by being arranged in a row so that the vertical portion 123 of another pattern 121 is positioned in the opening 124 formed in one pattern 121, and as the patterns 121, whose openings 124 are arranged to correspond to each other in a staggered form, are repeatedly arranged in the longitudinal direction, the patterns 121 can be uniformly arranged in the entire dummy region 120.

Meanwhile, the pattern 121 may be made of the same metal material as the circuit pattern formed in the substrate region 110 and mainly made of copper (Cu). Further, the pattern 121 may be formed at the same time when the circuit pattern of the substrate region 110 is formed.

Further, the dummy region 120 may secure a path for radiating heat through the openings 124 of the patterns 121, which correspond to each other in a staggered form, when the heat is applied during the manufacturing process of the semiconductor package substrate 100.

When the heat is applied during the manufacturing process of the package substrate 100, the pattern 121 of the dummy region 120 may expand to cause a change in the residual ratio of copper of the dummy region 120. At this time, the heat may be radiated in a zigzag form through the openings 124 of the patterns 121 to prevent the warpage due to the expansion of the pattern 121.

Meanwhile, as described above, since the molding process is performed on the substrate region 110 by applying the molding material, the inflow of the molding material into the dummy region 120 can be prevented by the patterns 121 formed in the dummy region 120. This is because among the patterns 121 continuously arranged in the dummy region 120, the horizontal portion 122 of the pattern 121 arranged in the position adjacent to the substrate region 110 act as an overflow prevention layer of the molding material to prevent the overflow of the molding material into the dummy region 120 from an edge portion of the substrate region 110.

At this time, the prevention of the inflow of the molding material into the dummy region 120 can prevent the defects of the package substrate 100 by generally uniformly applying the molding material without the collapse of the molding material applied to the substrate region 110.

The arrangement structure of the patterns 121 of the dummy region 120 configured as above may be adjusted to adjust the residual ratio of copper by the density of the patterns 121 and the horizontal portions 122 and the vertical portions 123 of the patterns 121 may be arranged in the entire dummy region 120 to be cross-coupled to each other so that the dummy region 120 can be formed in the entire region including a center portion and an outer portion with a uniform thickness to facilitate the control of the warpage by the dummy region 120.

Further, the residual ratio of copper by the density of the patterns 121 may be adjusted by adjusting the thickness and interval of the patterns 121 in addition to the shape and arrangement structure of the patterns 121 to minimize the difference in the residual ratio of copper between the dummy region 120 and the substrate region 110.

Like this, it is possible to minimize the warpage of the package substrate 100 by appropriately arranging the patterns 121 with the openings 124 in the dummy region 120 to thereby prevent the expansion of the patterns 121 and adjusting the density to thereby adjust the residual ratio of copper of the dummy region 120 to be similar to that of the substrate region 110. At this time, an edge pattern 130 may be formed along an outermost edge portion of the dummy region 120 to easily adjust the residual ratio of copper of the dummy region 120.

Meanwhile, the package substrate 100 of the present embodiment can prevent the warpage even by minimizing the difference in the residual ratio of copper between the upper and lower surfaces of the dummy region 120.

Further, it is possible to minimize the warpage by differently arranging the patterns 121 on the upper and lower surfaces of the dummy region 120. That is, as shown in FIG. 3, the pattern 121 with the opening 124 formed on the lower surface of the dummy region 120 may be arranged in a shape obtained by rotating the pattern 121 formed on the upper surface of the dummy region 120 by 90° (refer to A″ of FIG. 3). At this time, the pattern 121 arranged on the lower surface of the dummy region 120 may have the same shape as the pattern 121 formed on the upper surface of the dummy region 120.

Accordingly, the patterns 121 formed on the upper and lower surfaces in the same position of the dummy region 120 may be respectively arranged on the upper and lower surfaces of the dummy region 120 to cross each other as shown in FIG. 5. Typically, since the warpage due to the difference in the coefficient of thermal expansion mainly occurs by the difference in the coefficient of thermal expansion between the pattern 121 and a resin material, the warpage can be controlled by forming the patterns 121 on the upper and lower surfaces of the dummy region 120 to cross at right angles to each other in order for the patterns 121 on the upper and lower surfaces to complement each other by filling an empty space.

Like this, if the patterns 121 respectively formed on the upper and lower surfaces of the dummy region 120 are arranged to cross each other perpendicularly, the warpage of the substrate 100 can be controlled more easily than when the patterns 121 on the upper and lower surfaces are formed in the same direction.

This is because the pattern 121b on the lower surface of the dummy region 120 can complement the warpage that may occur in the portion in which the pattern 121a is not formed on the upper surface of the dummy region 120 and the pattern 121a on the upper surface of the dummy region 120 can complement the warpage that may occur in the portion in which the pattern 121b is not formed on the lower surface of the dummy region 120.

Meanwhile, the package substrate 100 of the present embodiment can improve the warpage by forming the patterns 121 on the upper and lower surfaces of the dummy region 120 in different shapes in addition to arranging the patterns 121 on the upper and lower surfaces of the dummy region 120 in different forms to thereby minimize the difference in the residual ratio of copper.

It is possible to minimize the difference in the residual ratio of copper between the entire upper and lower surfaces of the package substrate 100 by adjusting the shape of the pattern 121 on the lower surface of the dummy region 120 according to the difference in the residual ratio of copper between the substrate region 110 and the upper surface of the dummy region 120 of the package substrate 100.

For example, when the residual ratio of copper of the substrate region 110 of the upper surface of the package substrate 100 is high, the thickness of the pattern 121 on the lower surface of the dummy region 120 may be increased than the thickness of the pattern 121 on the upper surface of the dummy region to have a symmetrical residual ratio of copper in the entire package substrate 100.

Further, it is possible to increase the residual ratio of copper of the lower surface in the entire package substrate 100 by reducing the interval between the patterns 121b formed on the lower surface of the dummy region 120 than the interval between the patterns 121a formed on the upper surface of the dummy region 120 to thereby increase the density of the patterns 121.

In addition, as shown in FIG. 3, it is possible to selectively increase or decrease the residual ratio of copper of the upper and lower surfaces of the dummy region 120 by forming the edge pattern 130 on the upper and lower surfaces of the dummy region 120.

As described above, the semiconductor package substrate according to the present invention can prevent the warpage by minimizing the difference in the residual ratio of copper between the substrate region and the dummy region or between the upper and lower surfaces of the dummy region.

Further, the present invention can prevent the molding material applied to the substrate region from being introduced into the dummy region by the patterns formed in the dummy region of the semiconductor package substrate.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A semiconductor package substrate comprising:
a substrate region in which unit substrates are arranged in a lattice structure; and
a dummy region formed in an outer portion of the substrate region, wherein a plurality of patterns having openings are formed in the dummy region, and the openings of the patterns are arranged in a staggered form to correspond to each other while being arranged to correspond to each other.

2. The semiconductor package substrate according to claim 1, wherein the pattern consists of a horizontal portion and a pair of vertical portions bent from both ends of the horizontal portion so that the opening is formed in the position opposite to the horizontal portion.

3. The semiconductor package substrate according to claim 1, wherein the plurality of patterns are arranged in the dummy region in a plurality of rows, and an end of the vertical portion is positioned in the opening of the pattern.

4. The semiconductor package substrate according to claim 1, wherein the horizontal portions of the patterns are positioned in an edge portion of the substrate region in a row.

5. The semiconductor package substrate according to claim 1, wherein a residual ratio of copper of the dummy region is adjusted by the adjustment of the thickness and interval of the patterns.

6. The semiconductor package substrate according to claim 1, wherein the patterns are arranged on upper and lower surfaces of the dummy region, respectively, and the openings of the patterns are arranged to be open in different directions on the upper and lower surfaces of the dummy region.

7. The semiconductor package substrate according to claim 6, wherein the patterns are arranged in directions crossing each other in the same position of the upper and lower surfaces of the dummy region.

8. The semiconductor package substrate according to claim 1, wherein an edge pattern is selectively formed on one of the upper and lower surfaces of the dummy region.

9. A semiconductor package substrate comprising:
a substrate region in which circuit patterns are formed on unit substrates; and
a dummy region formed in an outer portion of the substrate region and having a plurality of patterns with openings, wherein a residual ratio of copper of the dummy region with respect to a residual ratio of copper of the substrate region is adjusted by arranging the openings of the patterns in the dummy region in a staggered form to correspond to each other.

10. The semiconductor package substrate according to claim 9, wherein the pattern consists of a horizontal portion and a pair of vertical portions bent from both ends of the horizontal portion so that the opening is formed in the position opposite to the horizontal portion.

11. The semiconductor package substrate according to claim 9, wherein the patterns are arranged on the upper and lower surfaces of the dummy region in directions perpendicular to each other.

12. The semiconductor package substrate according to claim 9, wherein an edge pattern is formed in an outer portion of the lower surface of the dummy region.

13. The semiconductor package substrate according to claim 9, wherein residual ratios of copper of the upper and lower surfaces of the dummy region are adjusted by the adjustment of the thickness and interval of the patterns formed on the upper and lower surfaces of the dummy region.

14. The semiconductor package substrate according to claim 9, wherein the plurality of patterns are arranged in the dummy region in a plurality of rows, and an end of the vertical portion is positioned in the opening of the pattern.

15. The semiconductor package substrate according to claim 9, wherein the horizontal portions of the patterns are positioned in an edge portion of the substrate region in a row.
